(19) United States
(12) Patent Application Publication
(10) Pub. No.: US 2025/0383398 A1
(43) Pub. Date: Dec. 18, 2025

(54) TESTING DEVICE FOR TESTING SEMICONDUCTORS

(71) Applicant: INTERNATIONAL BUSINESS MACHINES CORPORATION, ARMONK, NY (US)

(72) Inventors: John Knickerbocker, Monroe, NY (US); Mark Christopher Johnson, South Burlington, VT (US); Pablo Nieves, Pinebluff, NC (US); Ishtiaq Ahsan, Halfmoon, NY (US)

(21) Appl. No.: 18/745,999

(22) Filed: Jun. 17, 2024

(51) Int. Cl. G01R 31/28

(52) U.S. Cl. CPC G01R 31/2874; G01R 31/2886

(57) ABSTRACT

A semiconductor testing device includes a test head including one or more probe heads, and one or more electrical connectors, a heating/cooling unit configured to spread and remove heat within at least one device of one or more devices under test, a handler wafer, and a fixture configured to support the handler wafer. The semiconductor testing device is configured to power up at least one device of the one or more devices under test during testing.

### BACKGROUND

### Technical Field

The present disclosure generally relates to semiconductors, and more particularly, to testing semiconductor device structures, and methods of creation thereof.

### Description of Related Art

Semiconductor testing ensures the reliability, functionality, and quality of semiconductor devices, which are integral components in modern electronics. This testing process helps identify defects and failures in semiconductor chips before they are integrated into consumer electronics, automotive systems, and other applications. By detecting errors early, semiconductor testing reduces the risk of costly recalls and enhances product safety. Additionally, it supports the development of advanced technologies by allowing manufacturers to verify compliance with industry standards and improve product performance through iterative design refinements.

### SUMMARY

According to an embodiment, a semiconductor testing device includes a test head including one or more probe heads and one or more electrical connectors. There is a heating/cooling unit configured to spread and remove heat within at least one device of the plurality of devices, a handler wafer, and a fixture configured to support the handler wafer. The semiconductor testing device is configured to power up at least one device of the plurality of devices during testing.

In some embodiments, the one or more probe heads have a pitch ranging from 0.5 micrometer to 150 micrometers.

In some embodiments, the devices under test include at least one of: die under test (DUT), chiplet under test (CUT), wafer under test (WUT), stacked DUT, stacked CUT, module under test (MUT), and sub-assembly under test (SAUT).

In some embodiments, the one or more probe heads include the heating/cooling unit.

In some embodiments, the fixture is a thermally enabled fixture or a base mechanical stiffener and load support for the handler wafer.

In some embodiments, the one or more probe heads are made of Si, Cu, Solder, Al, SiGe, GaN, GaAs, Ni, Pt, Au, Pd, W, Mo, Diamond, AlN, BeO, SiN, and SiO2.

In some embodiments, the fixture is made of Si, Glass, Cu, SiGe, GaN, GaAs, W, Mo, Diamond, AlN, BeO, SiN, SiO2.

In some embodiments, the semiconductor testing device includes a first unit including at least one of: one or more solder bumps, and one or more microbumps, and a second unit comprising at least one of: one or more pads, and one or more vias. The first unit has a pitch in a range from 1 micrometer to 50 micrometers, and the second unit has a pitch in a range from about 0.5 micrometer to about 20 micrometers.

In some embodiments, the semiconductor testing device is configured to exert a force of 0.1 gram force per the second unit (gf/unit) to 5 gf/unit.

In some embodiments, the semiconductor testing device includes one or more interposer layers, one or more accelerator layers, and one or more memory layers.

In some embodiments, the semiconductor testing device includes one or more thermal sensors, at least one of: one or more load sensors, and one or more stress sensors, and one or more test contacts integrated with at least one of: the one or more devices under test, the one or more load sensors, and the one or more stress sensors.

In some embodiments, the semiconductor testing device is configured to test a 3D stacked plurality of devices and a 2D stacked plurality of devices. The semiconductor testing device is configured to test the one or more devices under test within a temperature range from −55° C. to 150° C.

In some embodiments, the heating/cooling unit includes at least one of: an air cooling/heating unit, a liquid cooling/heating unit, and a two-phase cooling/heating unit.

In some embodiments, the semiconductor testing device includes an artificial intelligence unit configured to utilize test data associated with the one or more devices under test to determine at least one of: a first number of probe heads and a second number of electrical connectors to be used for testing a new device.

According to an embodiment, a method for fabrication of a semiconductor testing device includes forming a test head including forming one or more probe heads and forming a one or more electrical connectors, forming a heating/cooling unit to spread and remove heat within at least one device of one or more devices under test, forming a handler wafer and forming a fixture to support the handler wafer. The semiconductor testing device is configured to power up at least one device of the one or more devices under test during testing.

In some embodiments, the method includes forming the heating/cooling unit within the one or more probe heads, and forming a thermally enabled fixture or a base mechanical stiffener and load support for the handler wafer.

In some embodiments, the method includes forming a first unit comprising at least one of: one or more solder bumps, and one or more microbumps, forming a second unit including at least one of: one or more pads, or one or more vias. The first unit has a pitch in a range from 1 micrometer to 50 micrometers, and the second unit has a pitch in a range from 0.5 micrometer to 20 micrometers.

In some embodiments, the method includes forming an artificial intelligence (AI) unit, utilizing, by the AI unit, test data associated with the one or more devices under test to determine at least one of: a first number of probe heads or a second number of electrical connectors to be used for testing a new device.

In some embodiments, the method includes forming one or more thermal sensors, forming at least one of: one or more load sensors, and one or more stress sensors, and forming one or more test contacts integrated with at least one of: the one or more devices under test, the one or more load sensors, or the one or more stress sensors.

According to an embodiment, a semiconductor testing device includes a test head, a handler wafer, a fixture configured to support the handler wafer, one or more stacked chiplet layers, one or more interposer layers, and one or more substrate layers.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates a semiconductor testing device, in accordance with some embodiments.

FIGS. 2A-2C illustrate various components of a semiconductor testing device, consistent with an illustrative embodiment.

FIG. 3 illustrates a block diagram of a method for forming the semiconductor testing device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

According to an embodiment, a semiconductor testing device includes a test head including one or more probe heads and one or more electrical connectors. There is a heating/cooling unit configured to spread and remove heat within at least one device of one or more devices under test, a handler wafer, and a fixture configured to support the handler wafer. The semiconductor testing device is configured to power up at least one device of the one or more devices under test during testing. The semiconductor testing device can power up any number of devices.

In some embodiments, the one or more probe heads have a pitch ranging from 0.5 micrometer to 150 micrometers. The small pitch size of the semiconductor testing device enables testing smaller devices compared to conventional testing devices.

In some embodiments, the devices under test include at least one of: die under test (DUT), chiplet under test (CUT), wafer under test (WUT), stacked DUT, stacked CUT, module under test (MUT), and sub-assembly under test (SAUT). Various types of semiconductor devices can be tested.

In some embodiments, the one or more probe heads include the heating/cooling unit. The heating/cooling unit can be part of the probe heads.

In some embodiments, the fixture is a thermally enabled fixture or a base mechanical stiffener and load support for the handler wafer. The fixture enables testing full thickness or thinned wafers.

In some embodiments, the one or more probe heads are made of Si, Cu, Solder, Al, SiGe, GaN, GaAs, Ni, Pt, Au, Pd, W, Mo, Diamond, AlN, BeO, SiN, and SiO2. Various types of materials are suitable to fabricate the probe heads.

In some embodiments, the fixture is made of Si, Glass, Cu, SiGe, GaN, GaAs, W, Mo, Diamond, AlN, BeO, SiN, SiO2. Various types of materials are suitable to fabricate the fixture.

In some embodiments, the semiconductor testing device includes a first unit including at least one of: one or more solder bumps, and one or more micro-bumps, and a second unit comprising at least one of one or more pads and one or more vias. The first unit has a pitch in a range from 1 micrometer to 50 micrometers, and the second unit has a pitch in a range from about 0.5 micrometer to about 20 micrometers. The bumps, micro-bumps, vias and pads can ensure electrical connections.

In some embodiments, the semiconductor testing device is configured to exert a force of 0.1 gram force per the second unit (gf/unit) to 5 gf/unit.

In some embodiments, the semiconductor testing device includes one or more interposer layers, one or more accelerator layers, and one or more memory layers. The integration of the interposers, accelerators and memory enable the semiconductor testing device to test a wide range of devices.

In some embodiments, the semiconductor testing device includes one or more thermal sensors, at least one of: one or more load sensors, and one or more stress sensors, and one or more test contacts integrated with at least one of: the one or more devices under test, the one or more load sensors, or the one or more stress sensors. Thermal sensors enable accurate measuring the temperature.

In some embodiments, the semiconductor testing device is configured to test a 3D stacked plurality of devices and a 2D stacked plurality of devices. The semiconductor testing device is configured to test the one or more devices under test within a temperature range from −55° C. to 150° C. Any type of devices, 2D and 3D can be tested by the semiconductor testing device.

In some embodiments, the heating/cooling unit includes at least one of: an air cooling/heating unit, a liquid cooling/heating unit, and a two-phase cooling/heating unit. The semiconductor testing device utilizes several types of fluid coolants.

In some embodiments, the semiconductor testing device includes an artificial intelligence unit configured to utilize test data associated with the one or more devices under test to determine at least one of: a first number of probe heads and a second number of electrical connectors to be used for testing a new device. The AI unit can enable intelligent testing and saving time and energy.

According to an embodiment, a method for fabrication of a semiconductor testing device includes forming a test head including forming one or more probe heads and forming a one or more electrical connectors, forming a heating/cooling unit to spread and remove heat within at least one device of one or more devices under test, forming a handler wafer and forming a fixture to support the handler wafer. The semiconductor testing device is configured to power up at least one device of the one or more devices under test during testing. The semiconductor testing device can power up any number of devices.

In some embodiments, the method includes forming the heating/cooling unit within the one or more probe heads, and forming a thermally enabled fixture or a base mechanical stiffener and load support for the handler wafer. The fixture enables testing full thickness or thinned wafers.

In some embodiments, the method includes forming a first unit comprising at least one of: one or more solder bumps, and one or more micro-bumps, forming a second unit including at least one of: one or more pads, or one or more vias. The first unit has a pitch in a range from 1 micrometer to 50 micrometers, and the second unit has a pitch in a range from 0.5 micrometer to 20 micrometers. The bumps, micro-bumps, vias and pads can ensure electrical connections.

In some embodiments, the method includes forming an artificial intelligence (AI) unit, utilizing, by the AI unit, test data associated with the one or more devices under test to determine at least one of: a first number of probe heads or a second number of electrical connectors to be used for testing a new device. The AI unit can enable intelligent testing and saving time and energy.

In some embodiments, the method includes forming one or more thermal sensors, forming at least one of: one or more load sensors, and one or more stress sensors, and forming one or more test contacts integrated with at least one of: the one or more devices under test, the one or more load sensors, or the one or more stress sensors. Thermal sensors enable accurate measuring the temperature.

According to an embodiment, a semiconductor testing device includes a test head, a handler wafer, a fixture configured to support the handler wafer, one or more stacked chaplet layers, one or more interposer layers, and one or more substrate layers. The semiconductor testing device can test full thickness or thinned wafers.

The concepts herein relate to thermal testing of the semiconductor devices, which is a component used in the semiconductor testing process, specifically designed to assess how semiconductor devices perform under varying temperature conditions. Such testing is performed to ensure that the semiconductor devices operate reliably across a wide range of temperatures, from the cold of outer space to the intense heat inside an operating engine or a powered-on computer. Typically, a thermal testing head is integrated into a test system that can precisely control the temperature of the semiconductor device under test. This can involve a mechanism to heat or cool the device to predetermined temperatures, simulating different environmental conditions. The device's performance metrics, such as electrical characteristics and operational reliability, are monitored and recorded throughout the process.

The testing process starts by mounting the semiconductor device onto the testing head, which has an interface that allows for both thermal and electrical connection. The device is then subjected to a series of temperature cycles, often ranging from below freezing to well above the typical operating temperature of most electronics. This cycling helps identify potential failures caused by thermal stress, such as expansion and contraction of materials, which might lead to mechanical failures or degradation of electrical properties. Throughout the testing, sensors monitor the device's response to the temperature changes, capturing data on how its electrical properties vary with temperature. This information can help in determining whether the semiconductor device can meet the specified performance standards in its intended operating environments. Such a semiconductor device is called “known good die,” KGD, which refers to individual semiconductor chips (or dice) that have been tested and verified to meet the operational specifications before being used in further applications, such as multi-chip modules or integrated into systems-on-chip. These dice are typically tested at the wafer-level using specialized test equipment that can ensure their functionality and performance.

The importance of KGD arises from the consideration to minimize the risk and cost associated with using defective dice in complex and often expensive electronic assemblies. By using known good dice, manufacturers can significantly enhance the reliability of the final products and avoid the costs associated with reworking or scrapping faulty assemblies. This is particularly critical in high-performance computing, telecommunications, and other industries where the integrity and dependability of each component are paramount.

In view of the above considerations, disclosed is a semiconductor testing device to ensure the durability and reliability of semiconductor devices, thus, to contribute to the overall quality assurance in the production of electronic devices.

Accordingly, the teachings herein provide methods and systems of a testing device to test semiconductor devices. The techniques described herein may be implemented in a number of ways. Example implementations are provided below with reference to the following figures.

### Example Semiconductor Testing Device Structure

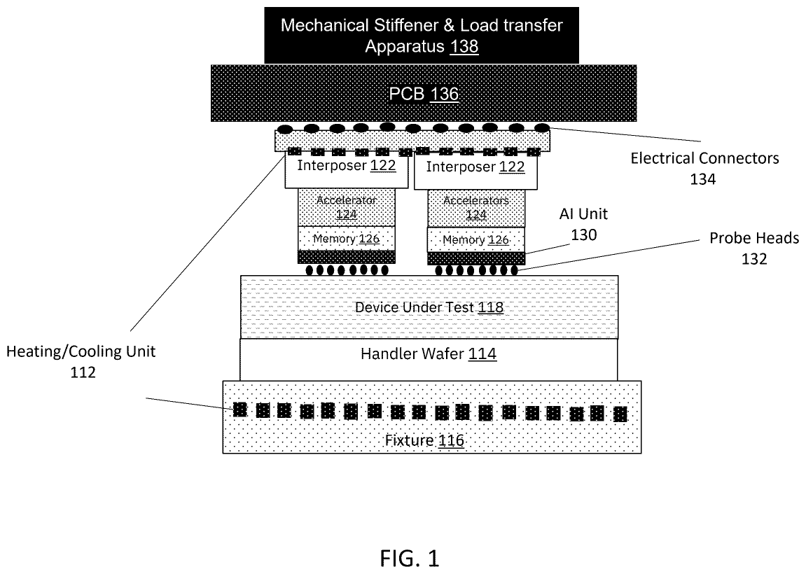

Reference now is made to FIG. 1, which is a simplified cross-sections view of a semiconductor testing device, consistent with an illustrative embodiment. In various embodiments, the semiconductor testing device 100 includes a test head, a heating/cooling unit 112, a handler wafer 114, and a fixture 116. The semiconductor testing device 100 can be used to test a device under test 118. In various embodiments, the device under test 118 can include a die under test (DUT), chiplet under test (CUT), wafer under test (WUT), stacked DUT, stacked CUT, module under test (MUT), and sub-assembly under test (SAUT).

The test head can include one or more probe heads 132, and one or more electrical connectors 134. The one or more probe heads 132 can be specialized tools designed to test and measure the thermal properties of the materials under various conditions. The one or more probe heads 132 can assess how the device under test will perform thermally in real-world applications, which can affect its reliability, efficiency, and lifespan. In some embodiments, the one or more probe heads 132 integrate a mechanism for heating and cooling the device under test 118 directly to allow the device under test 118 to be subjected to a range of temperatures, simulating different operating environments. The one or more probe heads 132 can make direct contact with the device under test 118 by using thermally conductive materials such as copper or silver, to ensure effective heat transfer. During the testing process, the one or more probe heads 132 not only can apply the required temperatures to the device under test 118 but also can measure the response of the semiconductor material. This includes changes in electrical characteristics due to temperature variations, which can indicate potential performance issues or failures.

The pitch size in conventional thermal test heads is the spacing between the contact points or pins (hereinafter “probes”) that connect the test head to the semiconductor device under test. This measurement dictates the compatibility of the test head with various types of semiconductor packages, particularly in terms of how densely the connections can be packed. Thermal test heads need to accommodate a range of pitch sizes to be versatile enough for different testing scenarios and device types. Although the pitch size can vary significantly depending on the specific application and the technology of the devices being tested, generally, the pitch sizes of the conventional probe heads range from about 200 micrometers to over 1000 micrometers. However, the semiconductor testing device 100 offers pitch sizes ranging from about 150 micrometers down to about 0.5 micrometer to align with the increasing density of connections on modern semiconductor devices. In some embodiments, this reduction in pitch size allows for more probe heads to be packed into a smaller area, facilitating the testing of more complex and higher performance devices that require numerous connections for full functionality verification. As such, the semiconductor testing device 100 can test a 3D stacked plurality of devices, a 2.×D stacked plurality of devices, and a 2D stacked plurality of devices.

In some embodiments, the one or more probe heads 132 can be made of Si, Cu, Solder, Al, SiGe, GaN, GaAs, Ni, Pt, Au, Pd, W, Mo, Diamond, AlN, BeO, SiN, and SiO2.

The one or more electrical connectors 134 can ensure that accurate electrical measurements can be made while the device under test 118 is subjected to controlled thermal conditions. The one or more electrical connectors 134 can be specifically designed to maintain a reliable electrical connection between the one or more probe heads 132 and the device under test 118, even as the device under test 118 undergoes temperature fluctuations during testing. The one or more electrical connectors 134 are highly conductive to facilitate the transmission of electrical signals without significant resistance or loss, and can be made from materials that can withstand the thermal stresses of heating and cooling cycles, involving metals such as gold or copper which offer both good conductivity and thermal stability.

In some embodiments, the design of the one or more electrical connectors 134 incorporate features that allow for a consistent contact pressure and minimal contact resistance with the device under test 118 for obtaining precise and repeatable measurements across various thermal conditions.

Conventionally, one significant issue arises when altering temperatures during semiconductor testing, particularly when transitioning the device under test from the controlled environment of a test chamber to the external environment. This shift often leads to the formation of condensation, a phenomenon that can severely damage both the device under test and the testing device itself. This problem is especially prevalent when moving the device under test from a cold environment, where they may have been subjected to low-temperature testing, to a warmer external environment. The sudden change in temperature can cause moisture to condense not only on the chamber walls and various testing device surfaces, but critically on the contact pins of the test head itself, i.e., on the probe heads. Such condensation can disrupt the electrical properties of the device under test and corrode sensitive electronic components. To combat condensation and mitigate condensation risks, the device under test is typically allowed to gradually acclimate to the new temperature, which can involve a waiting period of 10 to 20 minutes to ensure that all components have thoroughly dried.

In some embodiments, the integration of the heating/cooling unit 112 within the semiconductor testing device 100 presents a more efficient solution and enables a continuous testing process. The semiconductor testing device 100 can actively manage the temperature of the one or more probe heads 132, swiftly eliminating any moisture that has formed. By precisely controlling the temperature at the point of contact, this integrated heating/cooling unit 112 not only reduces the waiting time significantly but also enhances the accuracy and reliability of the testing process. The heating/cooling unit 112 can include an air heating/cooling unit, a liquid heating/cooling unit, or a two-phase heating/cooling unit.

The heating/cooling unit 112 can spread and remove heat within the device under test 118 or any other devices within the semiconductor testing device 100. In various embodiments, the semiconductor testing device 100 incorporates a thermal management system for testing device under test 118. The semiconductor testing device 100 can be designed to optimize temperature control during the testing phase, thereby enhancing test accuracy and reliability.

To that end, the heating/cooling unit 112 can act as a thermal regulation system that utilizes a micro-channel (uChannel) fluid circulation setup for heating and cooling of the device under test 118. The fluid can flow through the micro-channels embedded within the semiconductor testing device 100, enabling rapid and uniform temperature adjustments across the semiconductor testing device 100 surface in contact with the device under test 118. In some embodiments, the one or more probe heads 132 can surround the micro-channel structure that directly interfaces with the device under test 118 during testing. The one or more probe heads 132 can be crafted from materials with high thermal conductivity, such as copper (Cu), to facilitate efficient heat transfer between the semiconductor testing device 100 and the devices under test 118. This arrangement ensures that the device under test 118 and other components within the semiconductor testing device 100 reach and maintain the required test temperatures quickly and uniformly, mitigating any thermal gradients that could affect test results. This way, the semiconductor testing device 100 offers improvements over traditional testing setups, primarily through enhanced thermal management, reduced test cycle times, and increased reliability of the test results. In some embodiments, a liquid coolant, such as an oil, or nitrogen can be used to cool/heat the device under test 118. In some embodiments, the heating/cooling unit 112 is capable of conducting controlled temperature tests at various stages, including temperatures of about −55° C., about 25° C., about 85° C., to about 125° C., for simulating operational environments and assessing thermal responses of the device under test 118.

The handler wafer 114 can be used during processing of thinned wafers. Thinned wafers, which can be reduced in thickness to enhance performance and integration in electronic devices, can be particularly fragile and prone to damage. The handler wafer 114 can act as a supportive platform that secures these delicate wafers throughout various manufacturing and testing stages, ensuring their integrity. In some embodiments, the handler wafer 114 provides mechanical support and stability to the thinned wafer during testing processes to prevent warping, breaking, or other physical damages that could arise due to the thin and fragile nature of the thinned wafer. Additionally, the handler wafer 114 can facilitate the safe handling and transportation of the thinned wafers within the manufacturing facility. By attaching to the thinned wafer, the handler wafer 114 can allow for easier manipulation and movement between different processing stations without direct contact with the delicate surfaces of the thinned wafer.

The fixture 116 can support the handler wafer 114. The semiconductor testing device 100 can power up the device under test and/or any other components of the semiconductor testing device 100 during testing. The fixture 116 can be a thermally enabled fixture or base, which includes a mechanical stiffener and load support. In some embodiments, the fixture 156 can provide mechanical support to the handler wafer 114, in case of thinned wafer, and the device under test 118, ensuring structural integrity during various testing processes where physical and thermal stress can compromise the delicate components. In some embodiments, the fixture 116 can stabilize the device under test 118 during testing, preventing warping or damage under load. The mechanical stiffener in the fixture 116 can distribute weight and pressure evenly across the device's surface, which facilitates testing involving physical contact or pressure, such as during probing.

In some embodiments, the fixture 116 can be thermally enabled to effectively manage the temperature of the handler wafer 114 and the device under test 118. In an embodiment, the fixture 116 can include parts of the integrated heating/cooling unit 112 that maintain specific temperature conditions required for accurate test results. The combination of mechanical support and thermal management can ensure that the fixture 116 holds the device under test 118 securely and contributes to the reliability and accuracy of the testing process by maintaining optimal mechanical and thermal conditions.

In some embodiments, the fixture 116 is crafted primarily from silicon due to its favorable mechanical and thermal properties. In an embodiment, the fixture 116 is integrated with the heating/cooling unit 112, through which a specialized fluid circulates through the channels within the fixture 116. This circulation maintains temperature control, allowing for rapid and uniform removal or supply of heat to the device under test 118 during testing phases. The fixture 116 can be structured to support loads during testing and prevent physical deformation or displacement that could influence test outcomes. The fixture 116 material can be selected for its high thermal conductivity, which aids in the effective dissipation of heat during the testing process. Several options are provided for enhancing thermal transfer between the device under test 118 and the fixture 116 including the use of helium gas, a conductive oil, or thermal interface materials (TIMs), such as adhesive silver-filled polyimide (Ag-filled PI). TIMs can be selected based on their ability to efficiently transfer heat from the device under test to the heating/cooling unit 112 integrated within the fixture 116, thereby preventing overheating and ensuring the device under test 118 is maintained at optimal temperatures for accurate testing. In some embodiments, the fixture 116 is made of Si, Glass, Cu, SiGe, GaN, GaAs, W, Mo, Diamond, AlN, BeO, SiN, and SiO2.

In some embodiments, the one or more electrical connectors 134 and/or the one or more probe heads 132 can include a first unit and a second unit. The first unit can include one or more solder bumps or one or more microbumps. Bumps, microbumps and solder bumps (hereinafter “bumps”) can provide interconnections between various components in the stack of components and facilitate electrical and/or thermal connections.

In some embodiments, the bumps can be made of solder and serve not only as electrical pathways but also help in dissipating heat generated during the testing processes, aiding in thermal management. Microbumps, which are smaller than traditional bumps, can be made from materials such as copper or solder. The bumps can ensure reliable physical and electrical connections in complex semiconductor testing device's architectures and support both the mechanical stability of chip stacks and the integrity of signal and power transmission throughout the semiconductor testing device 100. In various embodiments, the first unit has a pitch in a range from about 1 micrometer to about 50 micrometers.

The second unit can include one or more pads or one or more vias. In some embodiments, pads and vias are used to provide electrical connectivity and circuit functionality. Pads can be copper-plated areas on the surface of a device or a semiconductor die where components, wires, or pins are soldered, and provide secure mechanical and electrical connections. Pads can serve as the contact points for different components and ensure that signals and power are efficiently distributed throughout the semiconductor testing device 100, contributing significantly to its overall performance. Vias, on the other hand, are small holes in a component that are filled or plated with conductive material and function as passageways for electrical signals to travel between different layers of the semiconductor testing device 100. Vias can be through holes (extending through substantially the entire stack), blind vias (connecting an outer layer to an inner layer but not visible from the other side), and buried vias (located entirely within inner layers and not visible from the surface). In some embodiments, both pads and vias facilitate structural and functional integration of components in multi-layer structure of the semiconductor testing device 100 and enable complex, multi-layered electrical connections while maintaining the integrity and reliability of the electronic circuitry. In some embodiments, the second unit has a pitch in a range from about 0.5 micrometer to about 20 micrometers. In some embodiments, the semiconductor testing device 100 can exert a force of about 0.1 gram force per pad to about 5 grams force per pad.

In some embodiments, the semiconductor testing device 100 can include one or more interposers 122, an accelerator 124, and a memory 126. The one or more interposers 122 can act as an intermediary layer that facilitates the connection between the one or more probe heads 132 and the device under test 118 to improve performance, reduce power consumption, and save space. The one or more interposers 122 can be made of materials such as silicon, glass, or organic substrates, and can contain a network of electrical connections or through-silicon vias (TSVs). The connections can allow for the vertical and horizontal routing of signals and power between different layers of the semiconductor testing device 100. In addition to improving electrical connectivity, the one or more interposers 122 can enhance the thermal and mechanical performance of the semiconductor testing device 100 and help distribute and manage the heat generated by different components and testing processes, thus aiding in the overall thermal management of the semiconductor testing device 100. In some embodiments, the one or more interposers 122 provide mechanical support, helping to alleviate stress caused by thermal expansion and contraction among different materials in the semiconductor testing device 100 to maintain the integrity and longevity of the components.

The accelerator 124 can enhance the testing process, either by speeding up the test or by improving the accuracy and repeatability of the results. The accelerator 124 can improve the efficiency of heating and cooling elements within the semiconductor testing device 100, allowing for rapid temperature changes and quick stabilization of the device under test 118, which is particularly important for assessing reliability and performance under thermal stress, where the device under test 118 undergoes multiple rapid thermal cycles.

Additionally, in some embodiments, the accelerator 124 can involve hardware or software enhancements that speed up data acquisition, processing, and analysis. Furthermore, the accelerator 124 can automate various aspects of the testing process, such as ensuring precise contact between probe heads and the device under test 118 or automating test sequences based on real-time data feedback to enhance test efficiency and reduce the potential for human error. The memory 126 can store the test results and test conditions.

The integration of interposers, accelerator and the memory can enable transitioning from coarser pitches to very fine pitches, incorporating built-in test circuits within the structure. Consequently, such an integration allows for selective testing of individual components, such as testing only the accelerator within a multi-component assembly.

In some embodiments, the semiconductor testing device 100 can include thermal sensors. In addition to the thermal sensors, the semiconductor testing device can include load sensors, and/or stress sensors. The thermal sensors, load sensors, and stress sensors can be part of one of the components of the semiconductor testing device 100, e.g., part of the probe heads, or be separate sensors connected to the semiconductor testing device 100.

In various embodiments, the thermal sensors, load sensors, and stress sensors can provide data to ensure the reliability and functionality of the devices under test at various conditions. The thermal sensors can monitor the temperature of the device under test by accurately measuring temperature changes induced during the testing processes. Load sensors can be used to measure the mechanical forces applied to the device under test 118 during testing. Stress sensors can detect and measure the strain and stress experienced by the device under test 118 during testing and provide information on how the device under test responds to physical stresses, such as those caused by thermal expansion, mechanical loads, or packaging processes. In some embodiments, the semiconductor testing device 100 includes test contacts. The test contacts can be integrated with the device under test 118, or with the load sensors or the stress sensors.

In some embodiments, the semiconductor testing device 100 can include an artificial intelligence unit, an AI unit 130. The AI unit 130 can utilize test data gathered from the device under test to determine the number of probe heads and/or the number of electrical connectors needed to be used for testing the device under test 118. This way, only the required number of probe heads and/or electrical connectors are used for the device under test, which can speed up the testing processes and reduce the energy consumption by the semiconductor testing device 100. Additionally, the AI unit 130 can utilize previous test data of various devices under test and then determine the characteristics of a new device under test.

In some embodiments, the semiconductor testing device 100 includes a printed circuit board, PCB 136, above the one or more probe heads 132. The semiconductor testing device 100 can further include a mechanical stiffener and load transfer support apparatus 138 on the back side of the PCB 136. PCB 136 can mechanically support and electrically connect electronic components using conductive pathways, or traces, etched from copper sheets laminated onto a non-conductive substrate. In some embodiments, the PCB 136 can be a single-sided (one copper layer), double-sided (two copper layers on both sides of the substrate), or multi-layered (outer and inner layers of copper, alternating with layers of substrate).

The mechanical stiffener and load transfer support apparatus 138 can enhance mechanical integrity and stability particularly where the PCB 136 or the device under test 118 is subject to mechanical stresses, which can lead to physical damage or failure of electronic components and connections. The mechanical stiffener and load transfer support apparatus 138 can be made from a rigid material such as metal, and can be attached to specific areas of the PCB to provide additional rigidity and support. The mechanical stiffener and load transfer support apparatus 138 can prevent the PCB from flexing and help protect solder joints and delicate components from mechanical stress and strain that can occur during the testing processes. In some embodiments, the mechanical stiffener and load transfer support apparatus 138 can function to distribute mechanical loads more evenly across the PCB 136 or the semiconductor testing device 100 assembly and absorb and disperse forces away from vulnerable areas, such as the bumps and probe heads, minimizing the risk of damage to the semiconductor testing device 100 and maintaining the integrity of electrical connections.

In various embodiments, the semiconductor testing device 100 incorporates the one or more probe heads 132, which are capable of making low-force contacts while still managing to power up the device under test 118 or other components of the semiconductor testing device 100. This represents a significant improvement over traditional testing devices, which typically do not power up a chip at pitches as fine as 150 microns. In contrast, the semiconductor testing device 100 facilitates the powering up of devices at an ultra-fine pitch of 50 microns or less. This capability ensures testing the functionality of the device under test 118 more efficiently and with greater precision.

The semiconductor testing device 100 can leverage wafer-level testing, where other components, e.g., the accelerator, can be tested across the entire wafer, or a specific substrate can be targeted for testing, focusing only on desired components. This method ensures that only components meeting the stringent quality standards are progressed to the next stages of manufacturing, thereby facilitating the assembly of known good dies. The probe heads are designed to minimize contamination and withstand extensive use, capable of testing thousands, even hundreds of thousands, of dies before requiring replacement. This durability can facilitate maintaining high testing throughput and reliability, ensuring the cleanliness of both the probe heads and the wafers throughout the testing process.

In some embodiments, temperature sensors (not shown) are incorporated within the one or more probe heads 132, or within the device under test 118, which can provide real-time feedback during testing. These temperature sensors dynamically control the temperature throughout the test process, ensuring the device under test 118, whether it be a single die, die stack, wafer, module, or sub-assembly, is maintained within optimal thermal conditions to accurately simulate real-world operational environments.

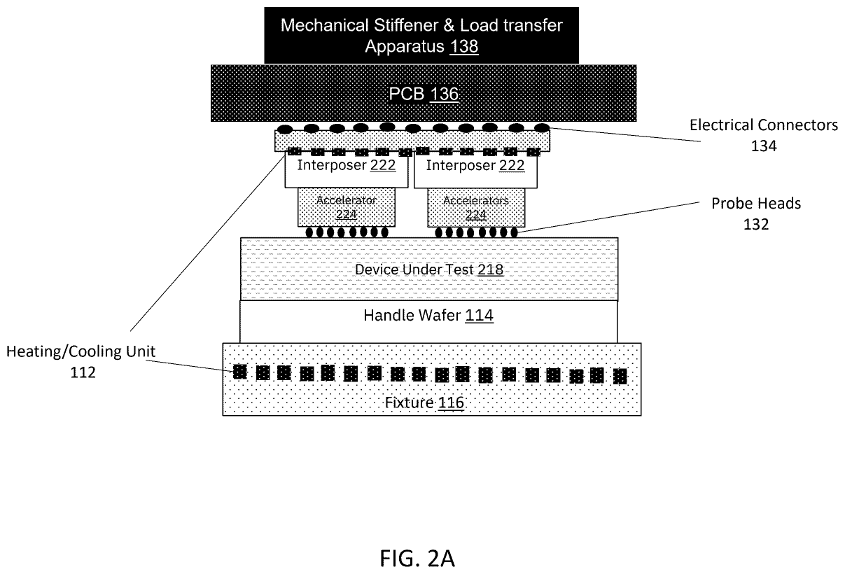

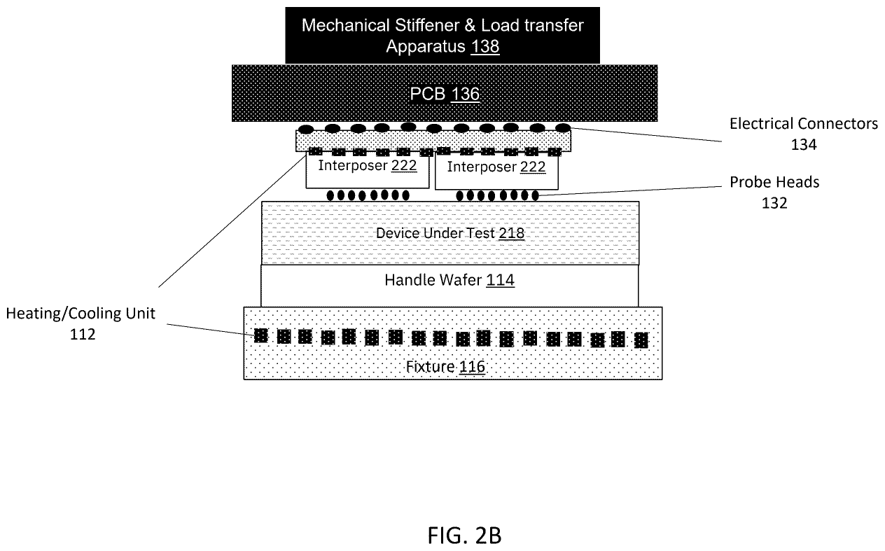

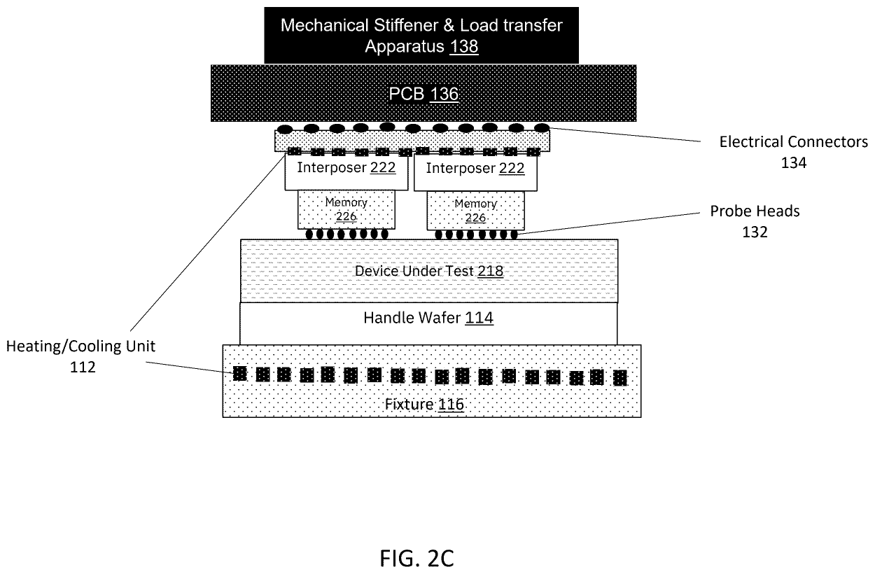

FIGS. 2A-2C illustrate various components of a semiconductor testing device, according to some embodiments. In some embodiments, the semiconductor testing device can accommodate and test device under test 218 with variable heights, with the capability of positioning arrays of plurality of probe heads 232 at various pitches. Such a flexibility can maintain contact with the device under test 218 across the interposer 222, and/or the accelerator 224, and/or the memory 226. FIG. 2A illustrates a semiconductor testing device 200A with an interposer 222 and an accelerator 224. The semiconductor testing device shown in FIG. 2A does not include a memory. FIG. 2B illustrates a semiconductor testing device with an interposer 222. The semiconductor testing device shown in FIG. 2B does not include the accelerator and the memory. FIG. 2C illustrates a semiconductor testing device that includes an interposer 222 and a memory 226. The semiconductor testing device shown in FIG. 2C does not include an accelerator.

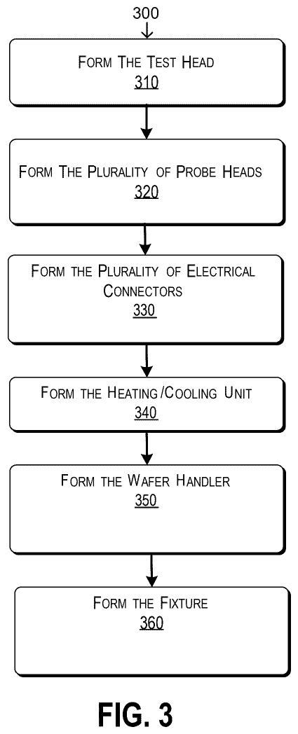

FIG. 3 illustrates a block diagram of a method 300 for forming the semiconductor testing device, in accordance with some embodiments. As shown by block 310, a test head is formed.

As shown by block 320, as part of forming the test head, one or more probe heads are formed.

As shown by block 330, as part of forming the test head, a one or more electrical connectors are formed.

As shown by block 340, a heating/cooling unit is formed. The heating/cooling unit can spread and remove heat within at least one device of the plurality of devices.

As shown by block 350, a handler wafer is formed.

As shown by block 360, a fixture is formed. The fixture can support the handler wafer. The semiconductor testing device can power up at least one device of the plurality of devices during testing.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor testing device, comprising:
a test head comprising:
one or more probe heads; and
one or more electrical connectors, wherein the one or more probe heads, the one or more electrical connectors are connected to one or more devices under test,
a heating/cooling unit configured to spread and remove heat within at least one device of the one or more devices under test;
a handler wafer below the one or more devices under test; and
a fixture configured to support the handler wafer, wherein the semiconductor testing device is configured to power up at least one device of the one or more devices under test during testing.

2. The semiconductor testing device of claim 1, wherein the one or more probe heads have a pitch ranging from 0.5 micrometer to 150 micrometers.

3. The semiconductor testing device of claim 1, wherein the one or more devices under test includes at least one of: die under test (DUT), chiplet under test (CUT), wafer under test (WUT), stacked DUT, stacked CUT, module under test (MUT), or sub-assembly under test (SAUT).

4. The semiconductor testing device of claim 1, wherein the one or more probe heads include the heating/cooling unit.

5. The semiconductor testing device of claim 1, wherein the fixture is a thermally enabled fixture or a base mechanical stiffener and load support for the handler wafer.

6. The semiconductor testing device of claim 1, wherein the one or more probe heads are made of Si, Cu, Solder, Al, SiGe, GaN, GaAs, Ni, Pt, Au, Pd, W, Mo, Diamond, AlN, BeO, SiN, and SiO2.

7. The semiconductor testing device of claim 1, wherein the fixture is made of Si, Glass, Cu, SiGe, GaN, GaAs, W, Mo, Diamond, AlN, BeO, SiN, SiO2.

8. The semiconductor testing device of claim 1, further comprising:
a first unit comprising at least one of: one or more solder bumps, or one or more microbumps, wherein the first unit has a pitch in a range from about 1 micrometer to about 50 micrometers; and
a second unit comprising at least one of: one or more pads, or one or more vias, wherein the second unit has a pitch in a range from about 0.5 micrometer to about 20 micrometers.

9. The semiconductor testing device of claim 8, wherein the semiconductor testing device is configured to exert a force of about 0.1 gram force (gf) per the second unit to about 5 gf per the second unit.

10. The semiconductor testing device of claim 1, further comprising:
one or more interposer layers;
one or more accelerator layers; and
one or more memory layers.

11. The semiconductor testing device of claim 1, further comprising:
one or more thermal sensors;
at least one of: one or more load sensors, or one or more stress sensors, and
one or more test contacts integrated with at least one of: the one or more devices under test, the one or more load sensors, or the one or more stress sensors.

12. The semiconductor testing device of claim 1, wherein the semiconductor testing device is configured to test a 3D stacked plurality of devices and a 2D stacked plurality of devices, and wherein the semiconductor testing device is configured to test the one or more devices under test within a temperature range from −55° C. to 150° C.

13. The semiconductor testing device of claim 1, wherein the heating/cooling unit includes at least one of: an air cooling/heating unit, a liquid cooling/heating unit, or a two-phase cooling/heating unit.

14. The semiconductor testing device of claim 1, further comprising an artificial intelligence unit configured to utilize test data associated with the one or more devices under test to determine at least one of: a first number of probe heads or a second number of electrical connectors to be used for testing a device.

15. A method for fabrication of a semiconductor testing device, the method comprising:
forming a test head comprising:
forming one or more probe heads; and
forming one or more electrical connectors;
forming a heating/cooling unit to spread and remove heat within at least one device of one or more devices under test;
forming a handler wafer; and
forming a fixture to support the handler wafer, wherein the semiconductor testing device is configured to power up at least one device of the one or more devices under test during testing.

16. The method of claim 15, further comprising:
forming the heating/cooling unit within the one or more probe heads; and
forming a thermally enabled fixture or a base mechanical stiffener and load support for the handler wafer.

17. The method of claim 15, further comprising:
forming a first unit comprising at least one of: one or more solder bumps, or one or more microbumps, wherein the first unit has a pitch in a range from 1 micrometer to 50 micrometers; and
forming a second unit comprising at least one of: one or more pads, or one or more vias, wherein the second unit has a pitch in a range from 0.5 micrometer to 20 micrometers.

18. The method of claim 15, further comprising:
forming an artificial intelligence (AI) unit; and
utilizing, by the AI unit, test data associated with the one or more devices under test to determine at least one of: a first number of probe heads or a second number of electrical connectors to be used for testing a device under test.

19. The method of claim 15, further comprising:
forming one or more thermal sensors;
forming at least one of: one or more load sensors, or one or more stress sensors, and
forming one or more test contacts integrated with at least one of: the one or more devices under test, the one or more load sensors, or the one or more stress sensors.

20. A semiconductor testing device, comprising:
a test head;
a handler wafer;
a fixture configured to support the handler wafer;
one or more stacked chiplet layers; and
one or more interposer layers.
